(19) United States
(12) Patent Application Publication
(10) Pub. No.: US 2007/0293137 A1
(43) Pub. Date: Dec. 20, 2007

(54) ACOUSTIC NOISE REDUCTION USING AIRFLOW MANAGEMENT

(75) Inventors: Martin J. Crippen, Apex, NC (US); Richard E. Harper, Chapel Hill, NC (US); John P. Karidis, Ossining, NY (US); Albert V. Makley, Raleigh, NC (US); Jason A. Matteson, Raleigh, NC (US); William J. Piazza, Holly Springs, NC (US); Malcolm S. Ware, Austin, TX (US)

Correspondence Address: CAREY, RODRIGUEZ, GREENBERG & PAUL, LLP;STEVEN M. GREENBERG, 950 PENINSULA CORPORATE CIRCLE, SUITE 3020, BOCA RATON, FL, 33487, US

(73) Assignee: International Business Machines Corporation, Armonk, NY (US)

(21) Appl. No.: 11/425,182

(22) Filed: Jun. 20, 2006

(51) Int. Cl. H05K 5/00; G06F 1/20; H05K 7/20

(52) U.S. Cl. 454/184; 361/695; 361/687

(57) ABSTRACT

A computer system includes a plurality of subsystems cooled by a cooling flow; at least one redirection device, a management module, and a blower for generating the cooling flow. The redirection device is associated with at least one subsystem and operable to redirect at least a portion of the cooling flow away from the subsystem. The subsystems, the at least one redirection device, and the blower are disposed along a common cooling flow path. The management module is configured to determine cooling requirements of the subsystems and to control the operation of the blower and the at least one redirection device to maintain a specified amount of cooling to the subsystems and to reduce acoustical noise generated by the blower.

### BACKGROUND OF THE INVENTION

1. Field of the Invention

The disclosure relates generally to computer systems and, more specifically, to a computer system and device increasing the cooling to particular overheating devices in the computer system while also reducing the acoustic output of the computer system.

2. Description of the Related Art

Many type of electronic devices are assembled in arrays of subsystems. For example, a single blade center may include several blade servers arrayed one next to another. A byproduct of the operation of the electronic devices is heat, and since the array of electronic devices are typically located in a confined area, heat generated by a single electronic device affects neighboring electronic devices and vice-versa. Many electronic devices, however, are sensitive to heat, and as a result, many electronic devices include one or more fans to cool the devices.

An issue associated with these arrays of subsystems occurs when one of the electronic devices overheats. The overheating may be for many reasons, but a typical reason for a subsystem to overheat is that one or more of the fans cooling that particular device have failed. If the overheating device was alone, the overheating may not be a serious issue. However, since the overheating device is in the midst of an array of other heat-producing devices, the issue of overheating is exacerbated. Once the temperature of the subsystem rises to a certain level, the device may fail or failsafe measures may be employed.

Certain of the failsafe mechanism to prevent a device from overheating is to either shut the device down or to throttle the operations of the device. Although the shutting down or throttling down of a particular device among an array of devices may not be a serious issue, in other instances, if the device is performing a critical function, the shutting/throttling down of the device is an occurrence to be avoided.

Another issue associated with cooling the arrays of subsystems is that the device used to generate the flow of cooling fluid is limited by how fast the cooling device can operate. Limits on the acoustical noise generated by computer devices have been imposed by OSHA, and these noise limits prevent current cooling devices from running faster and thus providing more cooling to the subsystems. There is, therefore, a need for system for increasing the cooling to particular overheating devices while also reducing the acoustic output of the computer system.

### BRIEF SUMMARY OF THE INVENTION

Embodiments of the invention address deficiencies of the art in respect to computer systems and provide a novel and non-obvious system and device for reducing acoustical noise generated by the computer system. The computer system includes a plurality of subsystems cooled by a cooling flow, at least one redirection device, a management module, and a blower for generating the cooling flow. The redirection device is associated with at least one subsystem and operable to redirect at least a portion of the cooling flow away from the subsystem. The subsystems, the at least one redirection device, and the blower are disposed along a common cooling flow path. The management module is configured to determine cooling requirements of the subsystems and to control the operation of the blower and the at least one redirection device to maintain a specified amount of cooling to the subsystems and to reduce acoustical noise generated by the blower.

In certain aspects, the redirection device is at least operable between a completely open position, a completely closed position, and a partially closed position. Also, the redirection device is disposed adjacent an aperture in a midplane within the computer system.

In other aspects, the redirection device is associated with a particular plurality of subsystems, and particular ones of the plurality of subsystems may be disposed within the cooling flow in parallel and other particular ones of the plurality of subsystems are disposed within the cooling flow in series. The redirection device may be associated with a single subsystem and/or a plurality of redirection devices may be associated with a single subsystem.

Additional aspects of the invention will be set forth in part in the description which follows, and in part will be obvious from the description, or may be learned by practice of the invention. The aspects of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The accompanying drawings, which are incorporated in and constitute part of this specification, illustrate embodiments of the invention and together with the description, serve to explain the principles of the invention. The embodiments illustrated herein are presently preferred, it being understood, however, that the invention is not limited to the precise arrangements and instrumentalities shown, wherein:

FIG. 1 is an exploded perspective view of a system for packaging a computer system in accordance with the inventive arrangements;

FIG. 2 is a cross-sectional view of the system for packaging a computer system in accordance with the inventive arrangements;

FIGS. 3A-3C are a schematic diagram of the airflow through the system;

FIG. 4 is a schematic diagram of a management module in accordance with the inventive arrangements; and

FIGS. 5A and 5B are perspective views showing a redirection device respectively in an open and a partially closed configuration.

### DETAILED DESCRIPTION OF THE INVENTION

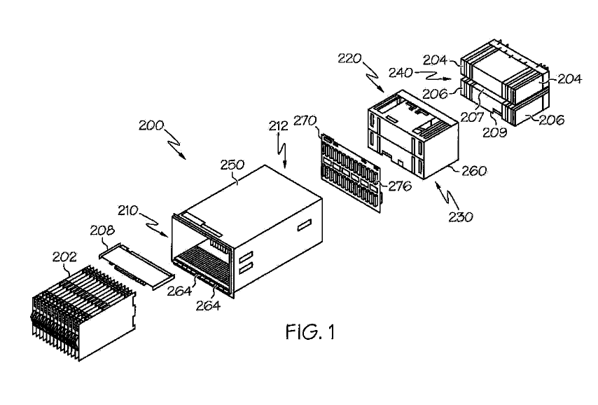

FIGS. 1-5 illustrate a acoustic noise and cooling management system 200. The system 200 includes a plurality of subsystems, such as blade servers 202 and peripheral devices 204, 206. cooled by an airflow; at least one redirection device 400; a management module 216; and a blower 207, 209 for generating the airflow. The redirection device 400 is associated with at least one subsystem and operable to redirect at least a portion of the airflow away from the subsystem 202, 204, 206. The subsystems 202, 204, 206, the at least one redirection device 400, and the blower 207, 209 are disposed along a common airflow path. The management module 216 is configured to determine cooling requirements of the subsystems 202, 204, 206 and to control the operation of the blower 207, 209 and the at least one redirection device 400 to maintain a specified amount of cooling to the subsystems 202, 204, 206 and to reduce acoustical noise generated by the blower 207, 209.

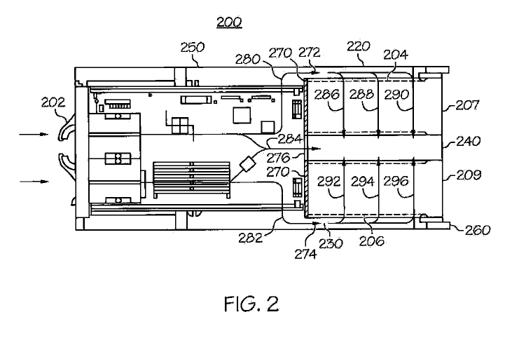

Referring to FIGS. 1 and 2, the system 200 may include multiple blade servers 202, a first (top) set of devices 204, a second (bottom) set of devices 206, and a midplane 270. In addition, the computer system may includes adjacent blowers 207 and 209. The system 200 includes a main chassis 250 and a switch-power-cooling (SPC) chassis 260. The main chassis 250 includes a first cavity 210 and a second cavity 212. The first cavity 210 is configured to receive the blade servers 202, as well as a peripheral device 208. Additionally, the main chassis 250 may be configured such that each of the blade servers 202 is hot pluggable into the first cavity 210

The SPC chassis 260 may be configured to retain the modules for the devices 204 and 206. In certain aspects, the devices 204 and 206 are hot pluggable into the SPC chassis 260. In addition, the SPC chassis 260 may be configured to plug into the main chassis 250. In particular, the SPC chassis 260 can be retained in the second cavity 212 of the main chassis 250. A common plenum 240 may be positioned between the modules for the devices 204 and 206 and between the blowers 207, 209. The upper plenum 220 may be formed above the SPC chassis 260 and between the SPC chassis 260 and the main chassis 250. The lower plenum 230 may be formed below the SPC chassis 260. In certain aspects, the upper plenum 220 and the lower plenum 230 are formed within the SPC chassis 260.

The midplane 270 may be a printed circuit board to which the blade servers 202 and devices 204 and 206 connect. In addition, the midplane 270 may include apertures 276 in a central portion of the midplane 270. The apertures 272 and 274 provide a path for air from the blades 202 to the first plenum 220 and second plenum 230, respectively. As shown by the arrows 280, 282, and 284, air used to cool the blades 202 may be split between the first plenum 220, the second plenum 230, and the common plenum 240.

Referring to FIG. 2, air in the first plenum 220 may be drawn through the first set of devices 204 and into the common plenum 240. Similarly, air in the second plenum 230 may be drawn through the second set of devices 206 and into the common plenum 240. This can be seen by the arrows 286, 288, 290, 292, 294, and 296. In this manner, air used to cool the blades 202 may also used for cooling the devices 204 and 206. Air used to cool only the blades 202 (shown by the arrow 284) and air used to cool the devices 204 and 206 (shown by arrows 286, 288, 290, 292, 294, and 296) may collected in the common plenum 240, and exhausted. Approximately 50% of the air exhausted from the blade 202 is exhausted through the rear of the blade 202 (i.e., arrow 284), and most of this air will enter the blowers 207, 209 via the apertures 276 in the midplane 270. Although the cooling fluid is referred to as air, the system is not limited in this manner as other types of cooling fluids are acceptable for use.

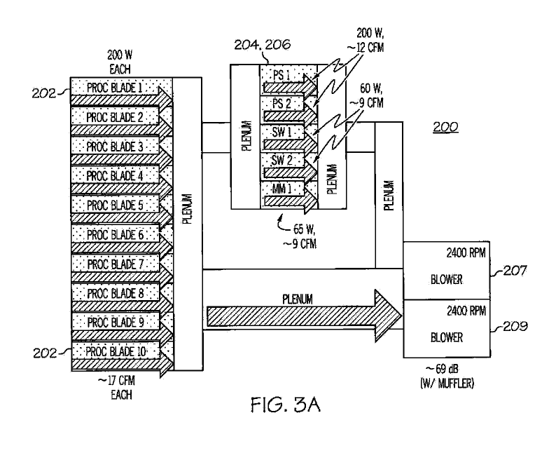

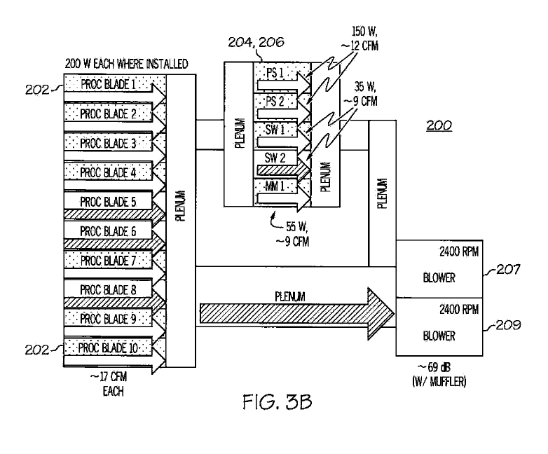

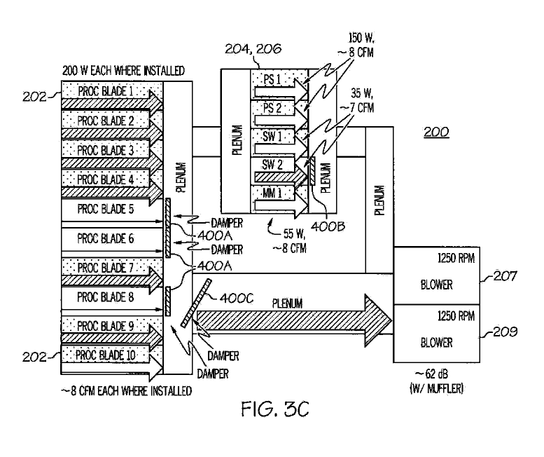

FIGS. 3A-3C schematically illustrate an example of the system 200 employing redirection devices 400 for increasing airflow to certain subsystems (i.e., the blades 202 and the peripheral devices 204, 206) requiring cooling and/or reducing acoustical noise generated by the blowers 207, 209. As readily recognized by those skilled in the art, the system 200 is not necessarily limited as to the particular configuration shown in the figures.

FIG. 3A illustrates the system 200 in which all the blades 202 and peripheral devices 204, 206 are running at full capacity, and thus generating maximum heat. The airflow throughput of the system 200 is typically designed to provide the maximum amount of airflow needed by each subsystem under a worst case scenario. In this circumstance, the blowers 207, 209 are running at 2400 RPM to generate sufficient airflow through the system 200 to cool the blades 202 and peripheral devices 204, 206.

In many circumstances, however, the maximum amount of airflow through the system 200 is not required because optional subsystems may not be installed and the installed subsystems may not be fully utilized. FIG. 3B illustrates such a situation in which certain of the blades 202 and peripheral devices 204, 206 are not installed and certain of the blades 202 and peripheral devices 204, 206 are not running at full capacity, but the redirection devices 400 have not been employed. Furthermore, the blowers 207, 209 are still running at 2400 RPM, and thus, the same amount of airflow is being pulled through the system 200.

FIG. 3C illustrates the use of the redirection devices 400 in combination with a reduction of blower speed to: (i) provide sufficient cooling to the subsystems, such as blades 202 and the peripheral devices 204, 206, and (ii) to reduce the acoustic output of the blowers 207, 209. As is common in the art, a blade center may not always be operating with a full complement of blades 202 and/or peripheral devices 204, 206, and in prior systems, full airflow is being provided to these unused slots in the blade center. However, in the present system 200, the redirection devices 400A, 400B may be employed to respectively redirect airflow from the unused blade slots and the unused peripheral slots.

Although certain of the redirection devices 400A, 400B may be associated with specific blades 202 or peripheral devices 204, the system 200 is not limited in this manner. Certain of the redirection devices 400C may be associated with a specific plenum and/or a specific grouping of blades 202 and/or peripheral devices 204. In this manner, the redirection of air from certain devices may be accomplished globally rather than individually.

By redirecting airflow from one particular blade 202 or peripheral device 204, 206, for the same total cooling flow through the system 200, the airflow to the other blades 202 or other peripheral devices 204, 206 within the system 200 may be increased. Moreover, when the cooling flow to one (or more) devices is reduced, the airflow to the other devices within the system 200 may be maintained and the total cooling flow through the system 200 may be decreased by reducing the speed of one or more of the blowers 207, 209. The reduction in speed of the blowers 207, 209 also reduces the acoustic output of the blowers 207, 209. In this manner, the redirection devices 400 may be used to increase airflow to certain devices and/or reduce the acoustic output of the blowers 207, 209.

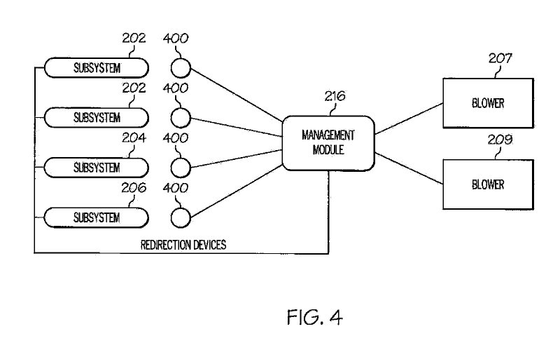

Referring to FIG. 4, the system 200 may include a management module 216. The management module 216 may be separate from the subsystems and/or a portion of the management module 216 may be incorporated within each of the subsystems. If multiple management modules 126 are provided, these management modules 216 may communicate between one another or the management modules 126 may operate independently.

The management module 216 makes the determination that a particular subsystem requires additional cooling or does not require the amount of cooling being provided. Many different manners of directly or indirectly determining the temperature of a particular device are known, and the management module 216 is not limited as to any manner so capable. For example, the management module 216 may employ a sensor to determine the temperature at a particular location relative to the subsystem. Other examples include reading a temperature of a CPU within the subsystem, determining power consumption of the subsystem, determining the utilization of the CPU within the subsystem and/or determining the temperature of a power supply within the server 12.

Additionally, the management module 216 may determine that a particular subsystem does not require cooling through an indication that the subsystem is not present. For example, positioning a particular blade 202 in a slot may register on a sensor, and if the sensor does register the blade 202 within the slot, the management module 216 may determine that the particular subsystem is not present.

Once the management module 216 makes the determination that a particular subsystem is overheating and requires additional cooling, the management module 216 controls the redirection devices 400 and/or the speed of the blowers 207, 209 to redirect airflow to the overheating subsystem and/or increase the total airflow within the system 200. Conversely, if the management module 216 makes the determination that a particular system does not require a full complement of airflow for cooling (e.g., the subsystem is running cooler than necessary), the management module 216 controls the redirection devices 400 and/or the blowers 207, 209 to redirect airflow away from the subsystem and/or decrease the total airflow within the system 200.

Since certain of the subsystems may be in parallel and/or series airflow paths with one another, the management module 216 may take into account how changing the airflow to one particular subsystem may effect the airflow to another particular subsystem. The manner and/or algorithms used by the management module 216 to take into account the effects of changing the airflow to one particular subsystem may effect the airflow to another particular system is not limited to a particular type.

In this manner, the management module 216 may control the redirection devices 400 and/or the speed of the blowers 207, 209 to provide sufficient airflow to all of the subsystems to meet the cooling requirements of the subsystems while reducing the amount of acoustic noise generated by the blowers 207, 209. Since the thermal loads created by the subsystems may constantly vary, the management module 216 may be configured to constantly update the configuration of the redirection devices 400 and/or the speed of the blowers 207, 209 to compensate for the changing cooling requirements of the subsystems.

Certain of the functional units described in this specification have been labeled as modules, in order to more particularly emphasize their implementation independence. For example, a module may be implemented as a hardware circuit comprising custom circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in software for execution by various types of processors. An identified module of executable code may, for instance, comprise one or more physical or logical blocks of computer instructions which may, for instance, be organized as an object, procedure, or function. Nevertheless, the executables of an identified module need not be physically located together, but may comprise disparate instructions stored in different locations which, when joined logically together, comprise the module and achieve the stated purpose for the module.

A module of executable code could be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different storage devices, and may exist, at least partially, merely as electronic signals on a system or network.

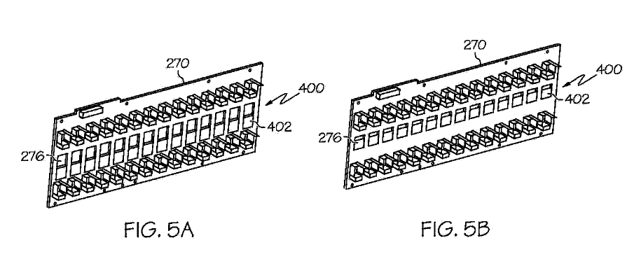

Many types of redirection devices 400 are known capable of redirecting the airflow, and the present system 200 is not limited in the manner or particular device in which the airflow is modified. For example, devices such as, programmable louvers, dampers, or shutters may be used to increase the airflow to certain subsystems and/or to increase the airflow to other subsystems. An example a redirection device 400 is illustrated in FIGS. 5A and 5B.

Although not limited in this manner, the redirection device 400 may be incorporated into the midplane 270. The midplane 270 includes apertures 276 through which air flows from the blades 202 to the blowers 207, 209, and each aperture 276 may be fitted with a shutter 402 that partially and/or completely covers the aperture 276. Each aperture 276 may be associated with a particular blade 202 so that the partial or complete closure of the aperture 276 by a shutter 402 reduces the airflow to that particular blade 202. In FIG. 5A, the redirection device 400 is shown in a completely opened configuration, and in FIG. 5B, the redirection device 400 is shown in a partially closed configuration in which the shutter 402 partially covers the aperture 276.

The partial and/or complete covering of the aperture 276 by the shutters 402 is not limited in a particular manner. For example, an electromagnetic may be mounted on the top of the aperture 276, and a permanent magnet may be mounted in the shutter. A controller may then be used to vary the supply of electricity to the electromagnetic. Depending upon the polarity and amount of electricity to the electromagnet, the shutters 402 may be completely and/or partially opened or closed. Alternatively, the shutter 402 may be completely and/or partially closed through the use of a servo.

As another example, instead of shutters 402, the redirection device 400 may include a pair of adjacent perforated sheets (not shown) that slide relative to one another. The perforations in the sheet can be sized and positioned such that the a particular relative movement of one sheet to the other sheet changes the amount of cooling flow through the redirection device 400. In this manner, the cooling flow may be completely or partially redirected.

What is claimed is:

1. A computer system, comprising:
a plurality of subsystems cooled by a cooling flow;
at least one redirection device associated with at least one subsystem and operable to redirect at least a portion of the cooling flow away from the at least one subsystem;
a blower for generating the cooling flow; and
a management module, wherein
the subsystems, the at least one redirection device, and the blower are disposed along a common cooling flow path,
the management module configured to determine cooling requirements of the subsystems and to control the operation of the blower and the at least one redirection device to maintain a specified amount of cooling to the subsystems and to reduce acoustical noise generated by the blower.

2. The computer system of claim 1, wherein the redirection device is at least operable between a completely open position, a completely closed position, and a partially closed position.

3. The computer system of claim 1, further comprising a midplane and the redirection device is disposed adjacent an aperture in the midplane.

4. The computer system of claim 1, wherein the redirection device is associated with a particular plurality of subsystems.

5. The computer system of claim 4, wherein particular ones of the plurality of subsystems are disposed within the cooling flow in parallel.

6. The computer system of claim 4, wherein particular ones of the plurality of subsystems are disposed within the cooling flow in series.

7. The computer system of claim 1, wherein the redirection device is associated with a single subsystem.

8. The computer system of claim 7, wherein a plurality of redirection devices are respectively associated with a particular plurality of subsystems disposed within the airflow in parallel.

9. The computer system of claim 1, wherein a plurality of redirection devices are associated with a single subsystem.

10. The computer system of claim 1, wherein particular ones of the plurality of subsystems are disposed within the cooling flow in parallel and other particular ones of the plurality of subsystems are disposed within the cooling flow in series.

11. An acoustic noise and cooling management system for providing cooling to a plurality of subsystems of a computer system cooled by a cooling flow generated by a blower, comprising:
at least one redirection device associated with at least one subsystem and operable to redirect at least a portion of the cooling flow away from the at least one subsystem; and
a management module, wherein
the subsystems, the at least one redirection device, and the blower are disposed along a common cooling flow path,
the management module configured to detecting cooling requirements of the subsystems and to control the operation of the blower and the at least one redirection device to maintain a specified amount of cooling to the subsystems and to reduce acoustical noise generated by the blower.

12. The computer system of claim 11, wherein the redirection device is at least operable between a completely open position, a completely closed position, and a partially closed position.

13. The computer system of claim 11, the redirection device is disposed adjacent an aperture in a midplane within the computer system.

14. The computer system of claim 11, wherein the redirection device is associated with a particular plurality of subsystems.

15. The computer system of claim 14, wherein particular ones of the plurality of subsystems are disposed within the cooling flow in parallel.

16. The computer system of claim 14, wherein particular ones of the plurality of subsystems are disposed within the cooling flow in series.

17. The computer system of claim 11, wherein the redirection device is associated with a single subsystem.

18. The computer system of claim 17, wherein a plurality of redirection devices are respectively associated with a particular plurality of subsystems disposed within the cooling flow in parallel.

19. The computer system of claim 11, wherein a plurality of redirection devices are associated with a single subsystem.

20. The computer system of claim 11, wherein particular ones of the plurality of subsystems are disposed within the cooling flow in parallel and other particular ones of the plurality of subsystems are disposed within the cooling flow in series.
